(19) United States
(12) Patent Application Publication
(10) Pub. No.: US 2006/0261272 A1
(43) Pub. Date: Nov. 23, 2006

(54) Imaging system

(75) Inventors: Kiyokazu Yoshida, Kiyosu-city (JP); Hidehito Terazawa, Obu-city (JP); Tadashi Nakamura, Hoi-gun (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 11/415,277

(22) Filed: May 2, 2006

(30) Foreign Application Priority Data
May 17, 2005 (JP) 2005-143934

(51) Int. Cl. G02F 1/01; H01L 31/00

(52) U.S. Cl. 250/330

(57) ABSTRACT

An imaging system for use in a vehicle includes an imaging unit having a lens for imaging a state of affairs and a rotation mechanism for defining a state of the lens of the imaging unit. The rotation mechanism is operated to be either in a first position or in a second position. That is, the first position of the rotation mechanism arranges the lens in a state of separation from a room in the vehicle, and the second position of the rotation mechanism arranges the lens in a state of exposure to the room in the vehicle.

### CROSS REFERENCE TO RELATED APPLICATION

This application is based on and claims the benefit of priority of Japanese Patent Application No. 2005-143934 filed on May 17, 2005, the disclosure of which are incorporated herein by reference.

### FIELD OF THE INVENTION

The present invention generally relates to an imaging system for capturing an image in a vehicle.

### BACKGROUND OF THE INVENTION

Conventionally, an imaging system or a camera disposed in a vehicle is used to capture an image in and out of the vehicle. That is, for example, the imaging system is used to capture an image of an intruder in the vehicle. Japanese patent document JP-A-2004-289625 discloses a car security apparatus, system and method that monitors the inside and outside of an automobile.

However, the camera suffers from tar of tobacco, chemical substance such as a cleaner solution or the like, and mucus from driver's body part adhered on a lens when the lens of the camera is always open to an atmosphere in the vehicle.

### SUMMARY OF THE INVENTION

In view of the above-described and other problems, the present invention provides an imaging system that reduces opportunity for a lens of a camera in a vehicle to be exposed to an atmosphere in a vehicle.

The imaging system for use in a vehicle includes an imaging unit having a lens for imaging a state of affairs, and a rotation mechanism for defining a state of the lens of the imaging unit. The rotation mechanism is operated to be either in a first state or in a second state for defining the state of the lens, and the first position of the rotation mechanism arranges the lens in a state of separation from a room in the vehicle, while the second position of the rotation mechanism arranges the lens in a state of exposure to the room in the vehicle. In this manner, the camera is separated from the atmosphere in the vehicle for a decreased time. That is, the camera in the vehicle is retracted for protection from the exposure to the atmosphere and other substances when it is not in use.

Further, the first position of the rotation mechanism arranges the lens in a less obstructive state relative to a sight of a driver in the vehicle in comparison to the second position of the rotation mechanism. In this manner, the camera is more suitably arranged in the vehicle in terms of driving environment for a driver of the vehicle when the camera is not used for imaging.

Furthermore, the imaging system further includes an actuator for actuating the rotation mechanism and a controller for controlling the actuator. The actuator actuates the rotation mechanism to transit between the first position and the second position. The controller controls the actuator to cause the rotation mechanism to be in the first position when the vehicle is in use, and the controller controls the actuator to cause the rotation mechanism to be in the second position when the vehicle is not in use. In this manner, the lens of the camera suffers less from adhesion of tar of tobacco, chemical substances, human mucus or the like in the vehicle.

In this case, “the controller controls the actuator to cause the rotation mechanism to be in the first position when the vehicle is in use,” means that the actuator is controlled at least at one timing for the duration of vehicle operation including a timing of transition from non-operation to operation for causing the rotation mechanism to be put in the first position. Further, “the controller controls the actuator to cause the rotation mechanism to be in the second position when the vehicle is not in use,” means that the actuator is controlled at least at one timing for the duration of vehicle non-operation including a timing of transition from operation to non-operation for causing the rotation mechanism to be put in the second position.

For example, the imaging system may use an intrusion sensor for detecting an intrusion of a robber into the vehicle, and may control the actuator to cause the rotation mechanism to be put in the second state when the intrusion is detected by the detection sensor. In this manner, the camera is exposed to the atmosphere in the vehicle only in an occasion of intrusion, thereby making it difficult for the intruder to approach the vehicle from a dead angle of imaging or to turn away from the camera by using precaution.

The imaging system may have another sensor beside the camera for sensing a physical quantity that propagates in the room of the vehicle, and may switch the positions of a sensing portion of the another sensor between a third position that separates the sensing portion from the atmosphere in the room of the vehicle and a fourth position that exposes the sensing portion to the atmosphere in the room by using another actuator. In this manner, the actuator and the another actuator are controlled together for switching the rotation mechanisms between the first position in association with the third position and the second position in association with the fourth position. As a result, the camera and the another sensor have less time and opportunity to be exposed to the atmosphere in the room of the vehicle, and are put in an integrated control state.

The imaging system may have a flash for supporting imaging. In this case, the first position and the second position respectively correspond to an exposure state and an separation state of the camera and the flash to/from the atmosphere in the room of the vehicle. As a result, the flash has less time and opportunity to be exposed to the atmosphere in the room of the vehicle, and are put in an integrated control state.

### BRIEF DESCRIPTION OF THE DRAWINGS

Other objects, features and advantages of the present invention will become more apparent from the following detailed description made with reference to the accompanying drawings, in which:

FIG. 1 shows a perspective view of an imaging system for a vehicle in operation in an embodiment of the present invention;

FIG. 2 shows a perspective view of an imaging system for a vehicle not in operation in the embodiment of the present invention;

FIG. 3 shows a block diagram of the imaging system in the embodiment of the present invention;

FIG. 4 shows a side view of a console when a camera and a flash are retracted in a body of the console;

FIG. 5 shows a side view of the console when the camera and the flash are pulled out from the body of the console; and

FIG. 6 shows a flowchart of a program executed in a security ECU.

### DETAILED DESCRIPTION OF THE PREFERRED EMBODIMENTS

Embodiments of the present invention are described with reference to the drawings.

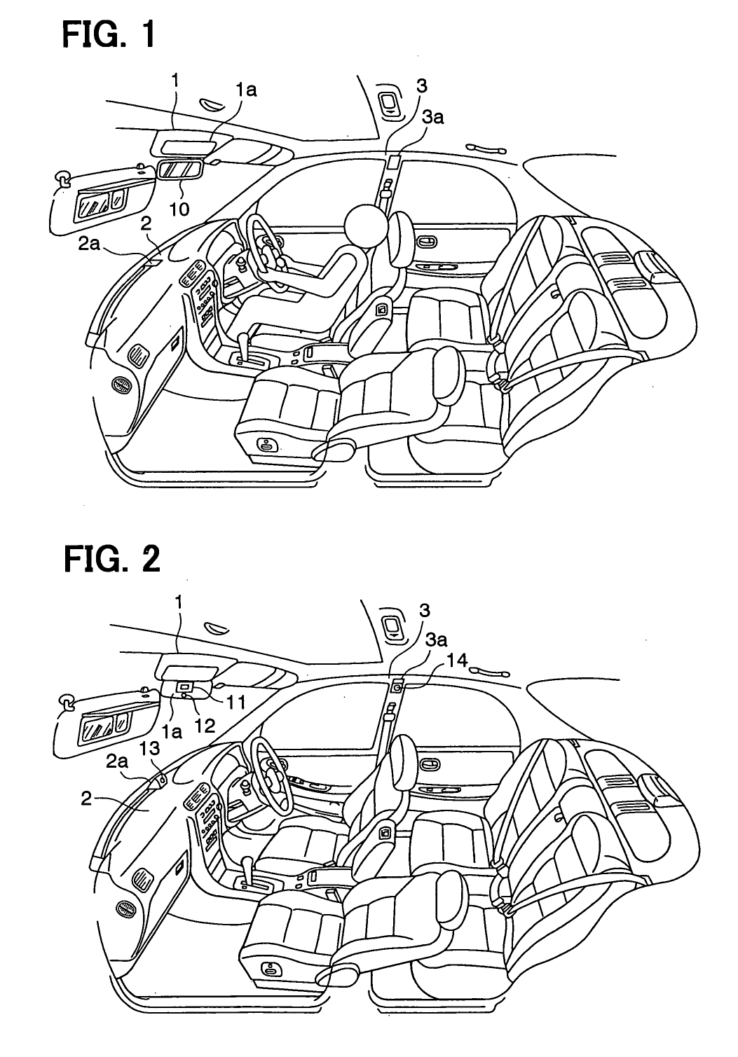

FIG. 1 shows a perspective view of an imaging system disposed in a vehicle in operation as an embodiment of the present invention. In FIG. 1, the vehicle is in operation and under control of a driver who is authorized to control the vehicle. An overhead console 1 disposed above a room mirror 10 houses a movable portion 1a of the imaging system embedded therein, and an instrument panel 2 has a movable portion 2a of the imaging system embedded at an upper center surface of the panel 2. A side pillar 3 has a movable portion 3a of the imaging system embedded at a top of the pillar 3.

The movable portions 1a, 2a, and 3a are rotatably moved under control of the imaging system to be protruded from the overhead console 1, from the instrument panel 2, and from the side pillar 3 respectively when the vehicle is not in use as shown in FIG. 2. The movable portion 1a has, on a room facing side in a position protruded from the console 1, a camera 11 capable of capturing a wide angle image or an all-round image accompanied by a flash 12 having LED or the like for imaging and lighting a view in the vehicle. The movable portion 2b has, on the room facing side in a position protruded from the panel 2, an infrared sensor 13. The movable portion 3b has, on the room facing side in a position protruded from the pillar 3, a window sensor 14 for sensing breakage of windows.

The infrared sensor 13 has a infrared light emission unit and a infrared light reception unit for reflection of the infrared light. The emission unit and the reception unit are exposed toward the room in the vehicle for detecting an intruder into the vehicle as shown in FIG. 2.

The window sensor 14 has a microphone exposed toward the room in the vehicle for detecting a sound of window breakage as an indication of break-in into the vehicle.

In this manner, the camera 11, the flash 12, the infrared sensor 13, and the window sensor 14 are exposed toward the room in the vehicle by a rotation movement of the movable portions 1a, 2a and 3a when the vehicle is not in use.

The control over the movable portions 1a, 2a and 3a by the imaging system is described in detail in the following.

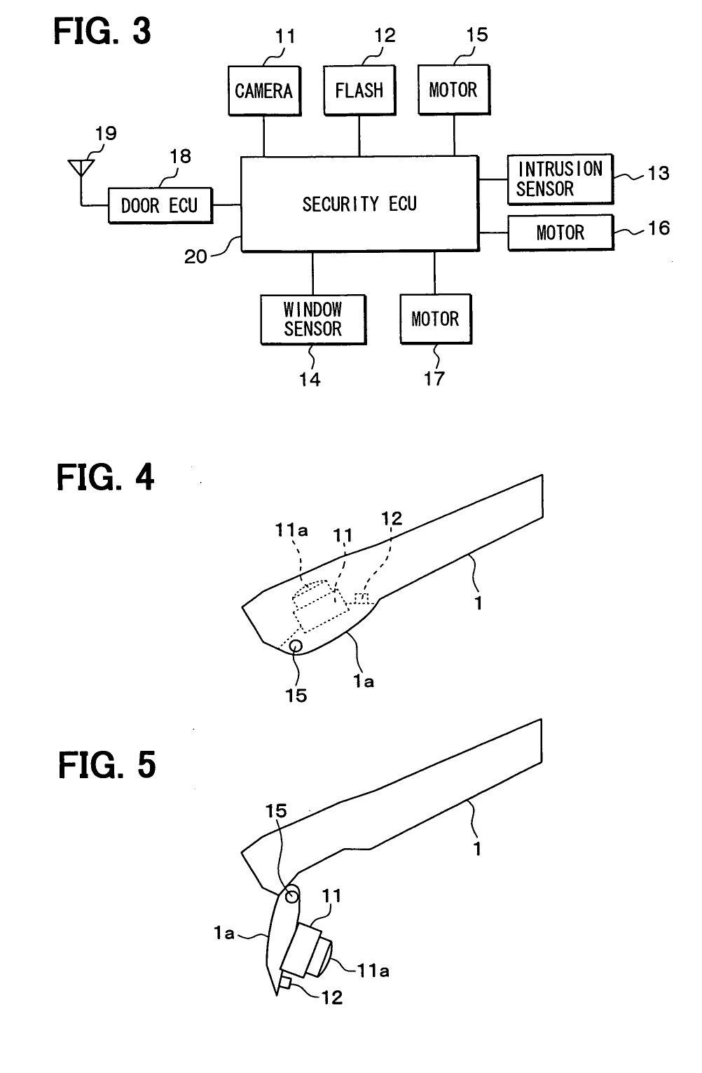

FIG. 3 shows a block diagram of the imaging system in the present embodiment of the invention. The diagram shows electrical connection between the components in the imaging system. The imaging system includes the camera 11, the flash 12, the infrared sensor 13, the window sensor 14, motors 15, 16, 17, a door ECU 18, an antenna 19, and a security ECU 20 in addition to the movable portion 1a, 2a and 3a.

The motor 15 is used to drive the movable portion 1a under control of the security ECU 20. The motor 16 is used to drive the movable portion 2a under control of the security ECU 20. The motor 17 is used to drive the movable portion 3a under control of the security ECU 20.

FIGS. 4 and 5 show side views of the console 1 for illustrating the movement of the movable portion 1a. The lower right in FIGS. 4 and 5 is a direction of the room in the vehicle, that is, the direction of the front seats and back seats. The movable portion 1a and the console 1 are movably connected around an axis, and the motor 15 drives the movable portion 1a around the axis. That is, the movable portion 1a is driven by the motor 15 to be in a position shown in FIG. 4 in an occasion, and is driven by the motor 15 to be in another position shown in FIG. 5 in another occasion. In this manner, a lens 11a of the camera 11 and a light emission unit of the flash 12 are retracted in the console 1 for separation from the atmosphere in the vehicle by a rotational movement of the movable portion 1a in an occasion, and are exposed to the atmosphere in the vehicle in another occasion.

The movable portion 2a is driven by the motor 16 in the same manner as the movable portion 1a. That is, the movable portion 2a and the panel 2 are movably connected around an axis, and the motor 16 drives the movable portion 2a around the axis. The movable portion 2a is driven by the motor 16 to retract the light emission unit and the light reception unit of the infrared sensor 13 in the panel 2 for separation from the atmosphere in the vehicle in an occasion, and is also driven to exposed the emission/reception unit toward the room in the vehicle in another occasion.

The movable portion 3a is driven by the motor 17 in the same manner as the movable portion 1a. That is, the movable portion 3a and the pillar 3 are movably connected around an axis, and the motor 17 drives the movable portion 3a around the axis. The movable portion 3a is driven by the motor 17 to retract the microphon of the window sensor 14 in the pillar 3 for separation from the atmosphere in the vehicle in an occasion, and is also driven to exposed the microphone toward the room in the vehicle in another occasion.

The door ECU 18 controls locking and unlocking of doors in the vehicle. For example, the door ECU 18 locks the door when it receives an authorized door lock request signal from a key-less entry terminal such as a smart key or the like carried by a user through the antenna 19. The door ECU 18 unlocks the door when it receives an authorized door unlock request signal. The lock signal and the unlock signal may be a same signal or may be different signals. The door ECU 18 outputs a signal to the security ECU 20 when the door is locked and the door is unlocked.

The security ECU 20 includes a microcomputer of well-known type having a CPU, a RAM, a ROM and the like. The security ECU 20 also includes non-volatile memories such as a flash memory, a backup RAM, a hard disk drive or the like that maintains its content while a power supply from a vehicle power source is interrupted. The CPU executes a program stored in the ROM, reads and writes data from/to the RAM and/or the non-volatile memories, reads data from the ROM and exchanges signals with the camera 11, the flash 12, the infrared sensor 13, the window sensor 14, the motors 15, 16, 17 and the door ECU 18.

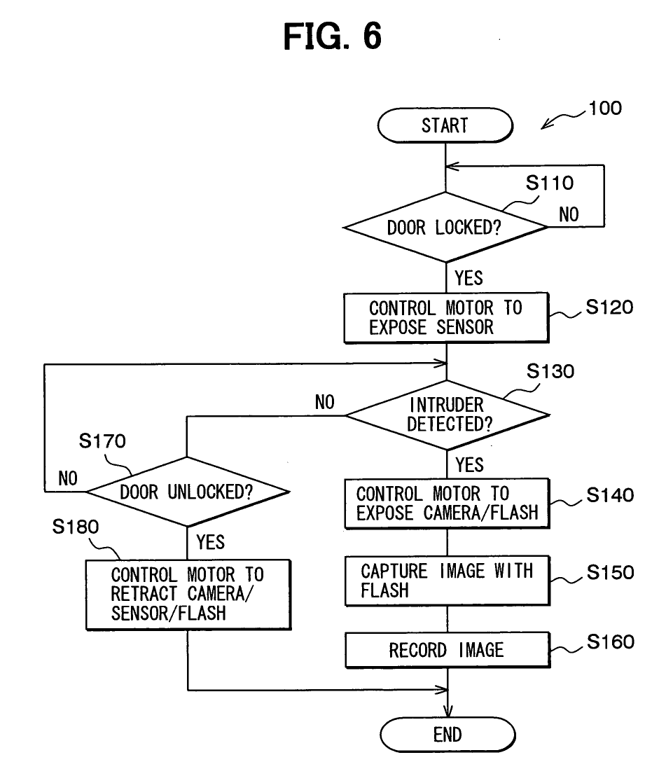

FIG. 6 shows a flowchart of a program 100 repetitiously executed by the CPU. The CPU in the security ECU 20 execute a process of the program 100 in the following manner.

In step S110, the process determines whether the door is locked. The process determines locking of the door based on reception of a door lock signal from the door ECU 18. The process proceeds to step S120 when the door is locked, and repeats step S110 when the door is not locked.

In step S120, the process controls the motors 16, 17 for driving the movable portions 2a, 3a to expose the infrared sensor 13 and the window sensor 14 toward the room in the vehicle. In this manner, the light emission unit and the light reception unit of the sensor 13 as well as the microphone of the window sensor 14 are exposed as shown in FIG. 2. In this case, the exposed infrared sensor 13 is in a position that obstructs a sight of the driver when the driver sits in a driver's seat. The exposed infrared sensor 13 is positioned to suitably detect a person in the vehicle.

In step S130, the process determines whether an intruder exists in the vehicle based on a signal from the infrared sensor 13. The process proceeds to step S140 when there is the intruder in the vehicle, and the process proceeds to step S170 when there is no intruder in the vehicle.

In step S140, the process controls the motor 15, and rotational movement of the movable portion 1a exposes the camera 11 and the flash 12. That is, the lens 11a of the camera 11 and the light emission unit of the flash 12 are moved into the vehicle to be exposed. In this case, the exposed camera 11 and the flash 12 are in a position that obstructs a sight of the driver toward the room mirror 10 when the driver sits in a driver's seat. The exposed camera 11 and the flash 12 are positioned to suitably capture a view in the vehicle.

In step S150, the process controls the flash 12 to light the room in the vehicle, and also controls the camera 11 to capture an image of the room in the vehicle at the same time. In this manner, the camera 11 captures an image of the room in the vehicle which is lit by the light from the flash 12, and the image is outputted to the security ECU 20.

In step S160, the process controls the non-volatile memories to acquire and stored the image outputted from the camera 11. In this case, the image may be sent through communication such as a radio transceiver (not shown in the figure) to an e-mail address of an owner of the vehicle or a security control center recorded in the non-volatile memories. Further, a horn of the vehicle or the like may be used to call attention to a condition of the vehicle.

In step S170, the process determines whether the door is unlocked based on reception of a door unlock signal from the door ECU 18. The process proceeds to step S180 when the door is unlocked, and the process returns to step S130 when the door is not unlocked.

In step S180, the process controls the motor 15 to retract the movable portion 1a having the camera 11 and the flash 12 into the overhead console 1. In this manner, the lens 11a of the camera 11 and a light emission unit of the flash 12 are retracted in the console 1 for separation from the atmosphere in the vehicle by a rotational movement of the movable portion 1a as shown in FIG. 1. Also in step S180, the process controls the motors 16, 17 to drive the movable portions 2a, 3a to retract the infrared sensor 13 and the window sensor 14 into the instrument panel 2 and the side pillar 3. In this manner, the light emission unit and the light reception unit of the infrared sensor 13 and the microphone of the window sensor 14 are retracted into the panel 2 or into the pillar 3 for separation from the room in the vehicle. The execution of the program concludes for the time after step S160 or step S180.

In this manner, the security ECU 20, under control of the program 100 executed in the CPU, exposes the infrared sensor 13 and the window sensor 14 in the room of the vehicle, detects the intruder, and captures an image of the room in the vehicle by the camera 11 and the flash 12 when the vehicle is not in use after locking the door. The captured image is stored in the non-volatile memories. Further, the security ECU 20 retracts the camera 11 with the flash 12, the infrared sensor 13 and the window sensor 14 respectively into the overhead console 1, the instrument panel 2, and the side pillar 3.

In this manner, the security ECU 20 controls exposure and separation of the camera 11 with the flash 12, the infrared sensor 13 and the window sensor 14 to and from the room in the vehicle. That is, the lens 11a of the camera 11, the light emission unit of the flash 12, the light emission unit and the light reception unit of the infrared sensor 13 and the microphone of the window sensor 14 are separated from the atmosphere in the room of the vehicle when the vehicle is in use, thereby reducing possibility of adhesion of tar of tobacco, chemical substances such as a cleaner, or mucus from driver's body part onto the lens 11a, other units or the like. Further, the driver has a better view when the vehicle is in use, because the camera 11, the sensor 13 are retracted.

Furthermore, the camera 11 is exposed at a timing when the infrared sensor 13 detects the intrusion of the intruder into the room of the vehicle, thereby making it difficult for the intruder to approach the vehicle from a dead angle of imaging or to turn away from the camera by using precaution.

Furthermore, the security ECU 20 executes another process for calling attention to the vehicle by sending e-mails through a communication device not shown in the figure to addresses of a security center and/or an owner of the vehicle stored in the ROM or the non-volatile memory upon detecting a glass breakage sound by the window sensor 14 when the vehicle is not in use, in parallel with the process of the program 100. In addition, the horn of the vehicle or the like is used to make a warning sound.

Although the present invention has been fully described in connection with the preferred embodiment thereof with reference to the accompanying drawings, it is to be noted that various changes and modifications will become apparent to those skilled in the art.

For example, the security ECU 20 may expose the camera 11 with the flash 12 in addition to the infrared sensor 13 with the windows sensor 14 to the room at the same time when the door of the vehicle is locked.

Further, the camera 11 may be disposed on the upper center portion of the instrument panel 2, or on the side pillar 3 or another pillar. The camera 11 may also be disposed on a ceiling of the room in the vehicle. For example, the camera 11 disposed in a concave portion of the ceiling in the vehicle may be covered from the atmosphere in the room by covering the concave portion in the first state, and may be exposed to the room in the second state by sliding off a covering of the concave portion.

Furthermore, the security ECU 20 may be a dedicated processor for executing a process that is identical to the process performed by execution of the program 100.

Furthermore, the use of the vehicle may be determined based on turning on/off of the main power source of the vehicle (IG, ACC etc.) instead of based on locking/unlocking the door of the vehicle.

Furthermore, the movable portions 1a, 2a, 3a may be driven based on an input from a user operation instead of based on the use/non-use of the vehicle. That is, the camera 11, the flash 12, the infrared sensor 13 and the window sensor 14 may be exposed to the room by driving the movable portions 1a, 2a, 3a, and may be separated from the room by reversing the movement of the movable portions 1a, 2a, 3a upon receiving the an input from the user respectively.

Furthermore, the movable portions 1a, 2a, 3a may be driven by a user's hand instead of a motor. That is, the camera 11 and other units on the movable portions 1a, 2a, 3a may be opened by the user's hand when the user enters into the vehicle, and may be retracted by the user's hand when the user comes out of the vehicle.

Furthermore, the infrared sensor 13 may be replaced by an ultrasonic sensor, a radio wave sensor or the like, as long as it detects the intrusion of the intruder into the vehicle.

Furthermore, the infrared sensor 13 and the window sensor 14 may be replaced by any sensor that receives propagation of physical quantity in the room of the vehicle.

Furthermore, the lens 11a, the light reception unit and the light emission unit may be at least partially covered or separated in the room in the first state in comparison with the second state. In this manner, the lens 11a and other units may be less susceptible to tar and other foreign matter adhered thereon.

Furthermore, the camera 11 may capture a view from the vehicle. For example, the camera 11 may capture a front view of the vehicle. In this case, the movable portions 1a, 2a, 3a may be opened in the first state when the vehicle is not in use by controlling the driving mechanisms, and may be retracted in the second state when the vehicle is in use by controlling the driving mechanisms.

Such changes and modifications are to be understood as being within the scope of the present invention as defined by the appended claims.

What is claimed is:

1. An imaging system for use in a vehicle comprising:
an imaging unit having a lens for imaging a state of affairs; and
a rotation mechanism for defining a state of the lens of the imaging unit, wherein the rotation mechanism is operated to be either in a first position or in a second position for defining the state of the lens,
the first position of the rotation mechanism arranges the lens in a state of separation from a room in the vehicle, and
the second position of the rotation mechanism arranges the lens in a state of exposure to the room in the vehicle.

2. The imaging system according to claim 1,
wherein the first position of the rotation mechanism arranges the lens in a less obstructive state relative to a sight of a driver in the vehicle in comparison to the second position of the rotation mechanism.

3. The imaging system according to claim 1 further comprising:
an actuator for actuating the rotation mechanism; and
a controller for controlling the actuator,
wherein the actuator actuates the rotation mechanism to cause transition between the first position and the second position,
the controller controls the actuator to cause the rotation mechanism to be in the first position when the vehicle is in use,
the controller-controls the actuator to cause the rotation mechanism to be in the second position when the vehicle is not in use, and
the imaging unit images the state of affairs in the room of the vehicle.

4. The imaging system according to claim 3 further comprising:
an intrusion sensor for detecting intrusion into the vehicle,
wherein the controller controls the actuator to cause the rotation mechanism to be in the second position based on the intrusion detected by the intrusion sensor when the vehicle is not in use.

5. The imaging system according to claim 1 further comprising:
a second sensor having a sensing portion for sensing a physical quantity that propagates in the room of the vehicle;
a second rotation mechanism for defining a state of the sensing portion of the second sensor;
a first actuator for actuating the rotation mechanism;
a second actuator for actuating the second rotation mechanism; and
a controller for controlling the first and the second actuators,
wherein the second rotation mechanism is operated to be either in a third position or in a fourth position,
the third position of the second rotation mechanism arranges the sensing portion of the second sensor in a state of separation from the room in the vehicle;
the fourth position of the second rotation mechanism arrange the sensing portion of the second sensor in a state of exposure to the room in the vehicle;
the first actuator actuates the rotation mechanism to cause transition between the first position and the second position, the second actuator actuates the second rotation mechanism to cause transition between the third position and the fourth position, the controller controls the first actuator to cause the rotation mechanism to be in the first position, and controls the second actuator to cause the second rotation mechanism to be in the third position when the vehicle is in use, and the controller controls the first actuator to cause the rotation mechanism to be in the second position, and controls the second actuator to cause the second rotation mechanism to be in the fourth position when the vehicle is not in use.

6. The imaging system according to claim 1 further comprising:
a light emitting device having an emission unit for emitting a light,
wherein the first position of the rotation mechanism arranges the lens and the emission unit of the light emitting device in a state of separation from the room in the vehicle, and
the second position of the rotation mechanism arranges the lens and the emission unit of the light emitting device in a state of exposure to the room in the vehicle.
